(19) United States
(12) Patent Application Publication
(10) Pub. No.: US 2008/0272355 A1
(43) Pub. Date: Nov. 6, 2008

(54) PHASE CHANGE MEMORY DEVICE AND METHOD FOR FORMING THE SAME

(75) Inventors: Sung-Lae Cho, Gyeonggi-do (KR); Byoung-Jae Bae, Hwaseong-si (KR); Jin-Il Lee, Gyeonggi-do (KR); Hye-Young Park, Gyeonggi-do (KR); Young-Lim Park, Gyeonggi-do (KR); Rak-Hwan Kim, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: Samsung Electronics Co., Ltd., Gyeonggi-do (KR)

(21) Appl. No.: 12/110,206

(22) Filed: Apr. 25, 2008

Related U.S. Application Data
(63) Continuation-in-part of application No. 11/753,291, filed on May 24, 2007.

(30) Foreign Application Priority Data
May 4, 2007 (KR) 10-2007-43664

(51) Int. Cl. H01L 47/00; H01L 21/00

(52) U.S. Cl. 257/2; 438/102; 257/E21.001; 257/E47.001

(57) ABSTRACT

A memory device using a phase change material and a method for forming the same are disclosed. One embodiment of a memory device includes a first insulating layer provided on a substrate and defining an opening; a first conductor including a first portion and a second portion, the first portion provided on a bottom of the opening, the second portion being continuously provided along a sidewall of the opening; a variable resistor connected to the second portion of the first conductor and provided along the sidewall of the opening; and a second conductor provided on the variable resistor.

### CROSS-REFERENCE TO RELATED APPLICATIONS

This application is a Continuation-in-Part of U.S. patent application Ser. No. 11/753,291, filed on May 24, 2007, now pending, and claims priority of Korean Patent Application No. 10-2007-43664, filed on May 4, 2007, the disclosures of both of which are hereby incorporated herein by reference in their entireties.

### BACKGROUND

1. Field of Invention

The embodiments disclosed herein relate to memory devices, and more particularly, to memory devices using a phase change material and methods for forming thereof.

2. Description of the Related Art

Phase change material may have two different states, e.g., a substantially crystalline state and a substantially amorphous state. The phase change material can further have at least one intermediate state between the substantially crystalline state and the substantially amorphous state. Thus, the phase change material may be employed in a semiconductor memory device such as a phase change memory device. Phase change material in the substantially amorphous state can have a higher resistivity than phase change material in the substantially crystalline state. Phase change material in the intermediate state can have a resistivity between those of the substantially amorphous and substantially crystalline states.

The phase of the phase change material can be changed according to a heat applied thereto. The heat may drive from resistance heating (Joule heating) of a conductor which is connected to a phase change material. Resistance heating occurs upon applying an electrical signal, e.g., a current, to ends of the phase change material. A resistance value is related to a contact area between the phase change material and the conductor connected thereto. The resistance value is inversely proportional to a contact area. Thus, as the resistance value increases, the phase change material can be heated more effectively under the same current. Accordingly, it would be desirable to reduce the contact area between the phase change material and the conductor connected thereto so that a phase change memory device can operate using a relatively low amount of power.

### SUMMARY

Embodiments exemplarily described herein may be characterized as providing memory devices capable of operating at a low power, and methods for forming the same.

One embodiment exemplarily described herein can be characterized as a memory device that includes a first insulating layer provided on a substrate and including an opening defined therein, a first conductor provided within the opening and including a first portion provided on a bottom of the opening and a second portion provided along a sidewall of the opening, a variable resistor provided along the sidewall of the opening and being connected to the second portion of the first conductor, and a second conductor provided on the variable resistor.

Another embodiment exemplarily described herein can be characterized as a semiconductor device that includes a substrate and a first conductor including a first portion and a second portion. A width of the first portion of the first conductor may be greater than a width of second portion of the first conductor. The semiconductor device may further include a second conductor and a variable resistor connected between the second portion of the first conductor and the second conductor. A width of the variable resistor may be less than the width of the first portion of the first conductor.

### BRIEF DESCRIPTION OF THE FIGURES

The accompanying figures are included to provide a further understanding of the embodiments of the present invention, and are incorporated in and constitute a part of this specification. The drawings illustrate exemplary embodiments of the present invention and, together with the description, serve to explain embodiments of the present invention. In the figures:

FIG. 1 is a vertical cross-sectional view of a phase change memory device according to one embodiment;

FIG. 2 is a cross-sectional view taken along line I-I′ shown in FIG. 1;

FIG. 3 is a cross-sectional view taken along line II-II′ shown in FIG. 1;

FIG. 4 is a cross-sectional view of a phase change memory device according to another embodiment;

FIG. 5 is a cross-sectional view taken along line III-III′ shown in FIG. 4;

FIG. 6 is cross-a sectional view of a phase change memory device according to yet another embodiment;

FIG. 7 is a cross-sectional view of a phase change memory device according to still another embodiment;

FIGS. 8 through 14 are sectional views illustrating an exemplary method of forming a phase change memory device according to one embodiment;

FIG. 15 is a sectional view of a memory cell array region and a peripheral circuit region in a phase change memory device according to one embodiment;

FIG. 16 is a view of one embodiment of a system including a phase change memory device; and

FIG. 17 is a block diagram of one embodiment of a memory card with a phase change memory device.

### DETAILED DESCRIPTION

Exemplary embodiments of the present invention will be described below in more detail with reference to the accompanying drawings. The embodiments may, however, be realized in different forms and should not be constructed as limited to the embodiments set forth herein. Rather, these embodiments are provided so that this disclosure will be thorough and complete, and will fully convey the scope of the present invention to those skilled in the art.

As used herein, terms such as “substrate,” “semiconductor substrate,” and “semiconductor layer” may refer to an arbitrary semiconductor-based structure. These terms may also refer a semiconductor-based structure having an arbitrary conductive region and/or insulating region. This semiconductor-based structure may, for example, include silicon, silicon-on-insulator (SOI), SiGe, Ge, GaAs, doped or undoped silicon, a silicon epitaxial layer supported by a semiconductor structure, other arbitrary semiconductor structures, or the like or combinations thereof.

In the figures, the dimensions of layers and regions are exaggerated for clarity of illustration. It will also be understood that when a layer (or film) is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference nurnerals refer to like elements throughout.

As used herein, terms such as “metallic layer” or “conductor” may refer to a metal, a conductive metal nitride, a conductive metal oxide, a conductive oxide nitride, a silicide, an alloy, or layered combination thereof. The metal may, for example, include Al, Cu, TiW, Ta, Mo, W, or the like, or an alloy thereof. The conductive metal nitride may, for example, include TiN, TaN, MoN, NbN, TiSiN, TiAlN, TiBN, ZrSiN, WSiN, WBN, ZrAlN, MoSiN, MoAlN, TaSiN, TaAlN, or the like. The conductive oxide nitride may, for example, include TiON, TiAlON, WON, TaON, or the like. The conductive metal oxide may, for example, include a conductive noble oxide such as IrO, RuO, or the like.

Embodiments exemplarily described herein relate to memory devices and methods for forming the same. More particularly, embodiments exemplarily described herein relate to a phase change memory device and a method for forming the same. Phase change material may, in embodiments exemplarily described herein, include a chalcogen compound. The phase change material may, in embodiments exemplarily described herein, include an XY compound, wherein the “X” component includes an element such as Te, Se, S, Po, or combinations thereof, and the “Y” component includes an element such as Sb, As, Ge, Sn, P, O, In, Bi, Ag, Au, Pd, Ti, B, N, Si, or combinations thereof.

In one embodiment, the phase change material may, for example, include a chalcogen compound such as Ge—Sb—Te(GST), Ge—Bi—Te (GBT), As—Sb—Te, As—Ge—Sb—Te, Sn—Sb—Te, In—Sn—Sb—Te, Ag—In—Sb—Te, 5A Group elements-Sb-Te, 6A Group elements-Sb—Te, 5A group elements-Sb—Se, 6A group elements-Sb—Se, or the like or combinations thereof, or a chalcogen compound including doped impurities and any of the above-identified chalcogen compounds. The impurities doped in the chalcogen compound may, for example, include N, O, Si, or the like or combinations thereof.

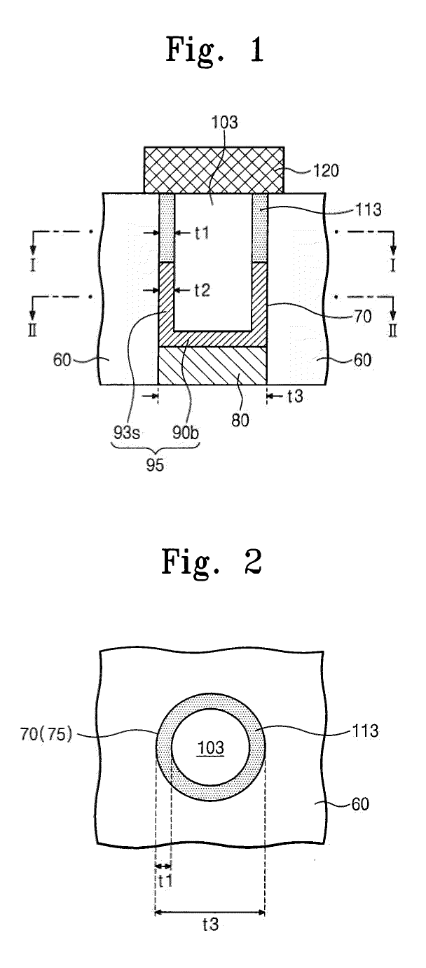

FIG. 1 is a vertical cross-sectional view of a phase change memory device according to one embodiment.

Referring to FIG. 1, a phase change memory device may, for example, include a variable resistor 113 provided in an opening 70 of a first insulating layer 60, and a first conductor 95. A second conductor 120 is connected to the variable resistor 113. The first conductor 95 and the second conductor 120 supply signals to change a resistance state of the variable resistor 113. The variable resistor 113 may include a phase change material.

In one embodiment, the phase change material 113 may include a material that is reversible between a plurality of phases (e.g., a substantially crystalline state, a substantially amorphous state, or any intermediate state therebetween) that represent respectively different resistance states. An electrical signal such as a current and a voltage, an optical signal, or radiation may be used as a signal in order to change the phase of the phase change material 113. For example, when a current flows between the first conductor 95 and the second conductor 120, a heat is supplied to the phase change material 113 thorough resistance heating, and a phase of the phase change material 113 may change according to a heat provided thereto.

The opening 70 in which the phase change material 113 and the first conductor 95 are provided may, for example, be contact hole, a linear contact hole, a curved groove, a linear groove, or a mixed linear and curved groove. The linear groove may be substantially parallel to a word line or a bit line. The opening 70 may, for example, include a bottom, a sidewall, and a top. The bottom of the opening 70 may include a portion adjacent to a substrate, i.e., adjacent to the first conductor 95. The top of the opening 70 may include a portion which is far from the substrate, i.e., adjacent to the second conductor 120. Additionally, a part of the sidewall of the opening 70 adjacent to the phase change material 113 may be referred to as a “top sidewall,” and a part of the sidewall of the opening 70 adjacent to the first conductor 95 may be referred to as a “bottom sidewall.”

In one embodiment, the phase change material 113 and the first conductor 95 may be confined within the opening 70 of the first insulating layer 60. Accordingly, the contact area between the phase change material 113 and the first conductor 95 and/or the contact area between the phase change material 113 and the second conductor 120 can be reduced. As a result, a memory device can be provided which can operate through a low power consumption.

A second insulating layer 103 may be provided in the center of the opening 70. The second insulating layer 103 may have a three-dimensional structure with first and second surfaces and a third face connecting the first and second surfaces. As used herein, the first surface of the second insulating layer 103 refers to the surface of the second insulating layer 103 adjacent to the second conductor 120 and may also be referred as the “top surface.” As used herein, the third surface of the second insulating layer 103 refers to the surface of the second insulating layer 103 adjacent to the sidewall of the opening 70 and may also be referred as the “side surface.” As used herein, the second surface of the second insulating layer 103 refers to the surface of the second insulating layer 103 adjacent to the bottom of the opening 70 and may also be referred as the “bottom surface.”

In one embodiment, the second insulating layer 103 is spaced apart from the first insulating layer 60 and is disposed substantially in the center of the opening 70. Therefore, the phase change material 113 and the first conductor 95 may be provided within a space defined between the first insulating layer 60 and the second insulating layer 103. Accordingly, the first conductor 95 surrounds the bottom surface of the second insulating layer 103 and a portion of the side surface of the second insulating layer 103 adjacent to the bottom surface. Also, the phase change material 113 surrounds a portion of the side surface of the second insulating layer 103 adjacent to the top surface of the second insulating layer 103. As used herein, the portion of the side surface of the second insulating layer 103 that is surrounded by the phase change material 113 may be referred to as the “upper side surface” of the of the second insulating layer 103. Likewise, the portion of the side surface of the second insulating layer 103 that is surrounded by the first conductor 95 may be referred to as the “lower side surface” of the second insulating layer 103. The second conductor 120 may be provided on the phase change material 113, the first insulating layer 60, and the second insulating layer 103.

A portion of the first conductor 95 provided on the bottom of the opening 70 may be referred to as a “first portion 90b” and a portion extending from the first portion 90b and provided on the bottom sidewall of the opening 70 may be referred to as a “second portion 93s.” Accordingly, the first portion 90b of the first conductor 95 is provided on the bottom surface of the second insulating layer 103 and the second portion 93b is provided on the lower side surface of the second insulating layer 103. The phase change layer 113 is provided on the sidewall of the opening 70 adjacent to the second conductor 120. That is, the phase change material 113 is provided on the upper side surface of the second insulating layer 103.

According to one embodiment, the phase change material 113 may be confined to a very narrow space between the first insulating layer 60 and the second insulating layer 103 such that the contact area between the phase change material 113 and the conductors 95 and 120 is relatively small. For example, the width t1 of the space between the first insulating layer 60 and the second insulating layer 103 is smaller than half the width t3 of the opening 70.

For example, the width of the first portion 90b of the first conductor 95, which is adjacent to the semiconductor substrate, is greater than the width of the second portion 93s of the first conductor 95, which is adjacent to the phase change material 113. Accordingly, a current density of the second portion 93s of the first conductor 95, which is adjacent to the phase change material 113, is higher than a current density of the first portion 90b of the first conductor 95, which is adjacent to the semiconductor substrate. Due to the relatively narrow width of the second portion 93s, the current density increases at a portion adjacent to the phase change material 113 and the efficiency with which the phase change material 113 is heated can be improved. On the other hand, because the width of the first portion 90b is relatively large, a contact resistance property between the first portion 90b and a conductive material below the first portion 90b can also be improved (e.g., a contact resistance between the first portion 90b and a conductive material below the first portion 90b can be reduced).

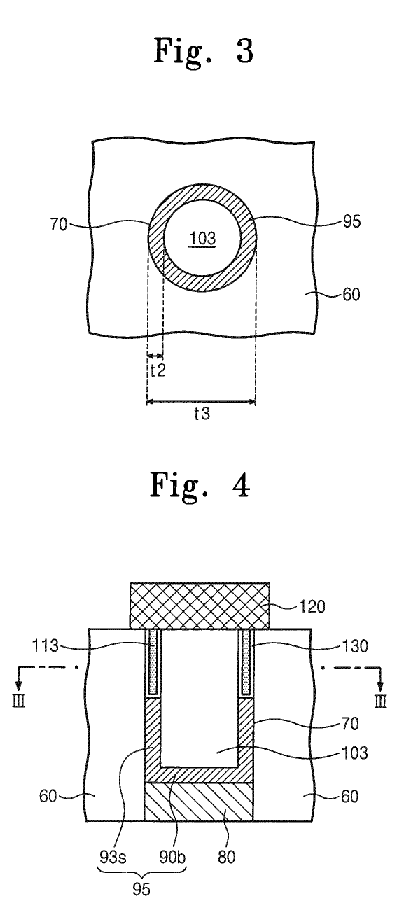

FIG. 2 is a sectional view taken along line I-I′ shown in FIG. 1. FIG. 3 is a sectional view taken along line II-II′ shown in FIG. 1.

Referring to FIG. 2, the opening 70 of the first insulating layer 60 may be a contact hole. The perimeter of the contact hole may be substantially circular but may vary according to manufacturing processes. The second insulating layer 103 is provided in the center of the opening 70. Accordingly, the geometric structure of the second insulating layer 103 may be characterized as substantially cylindrical. The phase change material 113 may have a ring shape when viewed from a plan view. In other words, the phase change material 113 may have a ring shape seen from a horizontal cross-section substantially parallel to a top surface of a substrate.

Referring to FIG. 3, the second portion 93s of the first conductor 95, which is adjacent to the phase change material 113, may have a ring shape. The first portion 90b of the first conductor 95 is provided on the bottom of the opening 70. Accordingly, the geometric structure of the first conductor 95 may be characterized as having a cup-type shape.

Referring back to FIG. 1, the phase change material 113 is provided along the top sidewall of the opening 70 and is adjacent to the second conductor 120. For example, the thickness (i.e., width) of the phase change material 113 is substantially equal to the width t1 of the space between the first insulating layer 60 and the second insulating layer 103 along the top sidewall of the opening 70 (i.e., along the upper side surface of the second insulating layer 103). Similarly, the second portion 93s of the first conductor 95 may be formed with a thickness (i.e., width) t2 along the bottom sidewall of the opening 70 (i.e., along the lower side surface of the second insulating layer 103). As used herein, the thickness of the phase change material 113 and the second portion 93s of the first conductor 95 (as well as the first portion 90b of the first conductor 95) refers to a dimension measured substantially horizontally between sidewalls of the opening 70. In one embodiment, the thickness t1 of the phase change material 113 and the thickness t2 of the second portion 93s of the first conductor 95 may be substantially the same. In one embodiment, the top surface of the phase change material 113 may be substantially coplanar with the top surface of the second insulating layer 103 and/or the top surface of the first insulating layer 60.

According to one embodiment, the portion phase change material 113 adjacent to the second conductor 120 and the portion of the phase change material 113 adjacent to the first conductor 95 may have substantially the same cross-sectional or geometric configuration. For example, a contact area between the first conductor 95 and the phase change material 113 and a contact area between the second conductor 120 and the phase change material 113 may have substantially the same size and/or substantially the same geometric configuration. According to one embodiment, one or both of the first conductor 95 and the second conductor 120 may function as a heating electrode capable of changing a phase of the phase change material 113. Accordingly, a phase change may occur within a region of the phase change material 113 adjacent to the first conductor 95 and/or within a region of the phase change material 113 adjacent to the second conductor 120. Thus, the phase change material 113 may change a phase within two regions such that a multi-level memory device can be realized using the phase change material 113.

According to one embodiment, a third conductor 80 may be provided between the first conductor 95 and the bottom of the opening 70. That is, the first conductor 95 is provided between the third conductor 80 and the phase change material 113. The third conductor 80 may have a relatively high thermal conductivity. The operating current of a structure in which the first conductor 95 is provided between the third conductor 80 and the phase change material 113 may be less than the operating current of a structure in which the thermally conductive third conductor 80 directly contacts the phase change material 113.

The first conductor 95 may include a metal such as Ti, Hf, Zr, V, Nb, Ta, W, Al, Cu, TiW, Mo, or the like or an alloy thereof, a binary metal nitride such as TiN, HfN, ZrN, VN, NbN, TaN, WN, MoN, or the like, a metal oxide such as IrO₂, RuO₂, or the like, a ternary metal nitride such as TiCN, TaCN, TiSiN, TaSN, TiAlN, TaAlN, TiBN, ZrSiN, WSiN, WBN, ZrAlN, MoSiN, MoAlN, TaON, TiON, WON, TaON, or the like, silicon, or combinations thereof. According to one embodiment, the first conductor 95 may be formed of TiN.

The second conductor 120 may include a metal such as Ti, Hf, Zr, V, Nb, Ta, W, Al, Cu, TiW, Mo, or the like or an alloy thereof, a binary metal nitride such as TiN, HfN, ZrN, VN, NbN, TaN, WN, MoN, or the like, a metal oxide such as IrO₂, RuO₂, or the like, a ternary metal nitride such as TiCN, TaCN, TiSiN, TaSN, TiAlN, TaAlN, TiBN, ZrSiN, WSiN, WBN, ZrAlN, MoSiN, MoAlN, TaON, TiON, WON, TaON, or the like, silicon, or combinations thereof. According to one embodiment, the second conductor 120 may be formed of Ti and TiN, which are sequentially stacked such that TiN is stacked over Ti. According to another embodiment, the second conductor 120 may be formed of Al, Al—Cu, Al—Cu—Si, WSi, Cu, TiW, Ta, Mo, W, or combinations thereof.

The third conductor 80 may include a metal such as Ti, Hf, Zr, V, Nb, Ta, W, Al, Cu, TiW, Mo, or the like or an alloy thereof, a binary metal nitride such as TiN, HfN, ZrN, VN, NbN, TaN, WN, MoN, or the like, a metal oxide such as IrO₂, RuO₂, or the like, a ternary metal nitride such as TiCN, TaCN, TiSiN, TaSN, TiAlN, TaAlN, TiBN, ZrSiN, WSiN, WBN, ZrAlN, MoSiN, MoAlN, TaON, TiON, WON, TaON, or the like, silicon, or combinations thereof. According to one embodiment, the third conductor 80 may be formed of W.

The first insulating layer 60 and the second insulating layer 103 may, for example, include an insulating material such as silicon oxide, silicon nitride, silicon oxynitride, or the like or combinations thereof. In one embodiment, the first insulating layer 60 and the second insulating layer 103 may be formed of substantially the same material.

FIG. 4 is a sectional view of a phase change memory device according to another embodiment.

Referring to FIG. 4, the phase change memory device may be similar to the phase change memory device exemplarily described with respect to FIGS. 1 to 3 but may include a seed layer 130. The seed layer 130 may be provided between the phase change material 113 and the first conductor 95. Moreover, the seed layer 130 may be provided between the phase change material 113 and the first and second insulating layers 60 and 103. The seed layer 130 may facilitate the formation of the phase change material 113 as is described in greater detail with respect to FIG. 12. The seed layer 130 may, for example, include a material such as TiO, TaO, ZrO, MnO, HfO, MgO, InO, NbO, GeO, SbO, TeO, or the like or combinations thereof.

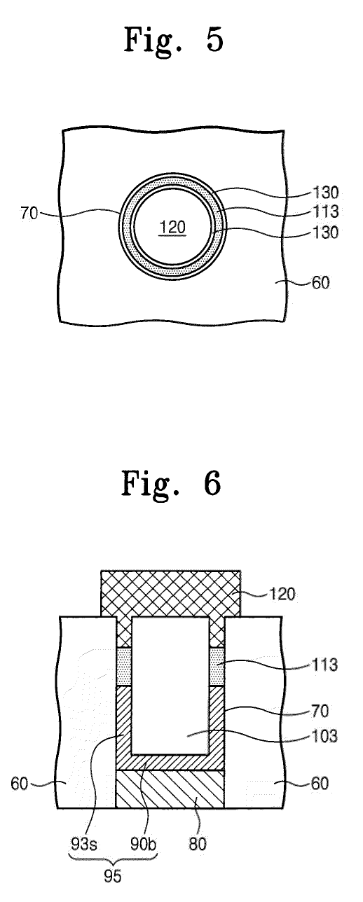

FIG. 5 is a sectional view taken along line III-III′ shown in FIG. 4.

Referring to FIG. 5, the seed layer 130 is provided between the phase change material 113 and the first and second insulating layers 60 and 103. Accordingly, the seed layer 130 surrounds the sidewall and the bottom of the phase change material 113. Additionally, the seed layer 130 may be provided between the phase change material 113 and the first portion 90b of the first conductor 95. In one embodiment, the seed layer 113 may be substantially amorphous. As shown in FIG. 5, the width of the phase change material 113 may not be substantially equal to the width t1 of the space between the first insulating layer 60 and the second insulating layer 103. Rather, the width of the phase change material 113 is narrower than the width t1 of the space between the first insulating layer 60 and the second insulating layer 103. Accordingly, the thickness of the phase change material 113 is less than the thickness t2 of the second portion 93s of the first conductor 95.

FIG. 6 is a cross-sectional view of a phase change memory device according to further another embodiment of the present invention.

Referring to FIG. 6, the phase change memory device may be similar to the phase change memory device exemplarily described with respect to FIGS. 1 to 3 but a portion of the second conductor 120 may extend into the opening 70. Accordingly, the top surface of the phase change material 113 may be lower than the top surface of the second insulating layer 103 and/or the top surface of the first insulating layer 60. In one embodiment, a geometric structure of the second conductor 120 adjacent to the phase change material 113 may be a ring shape. It will also be appreciated that the phase change memory device shown in FIG. 6 may further include a seed layer such as that exemplarily described with respect to FIGS. 4 and 5.

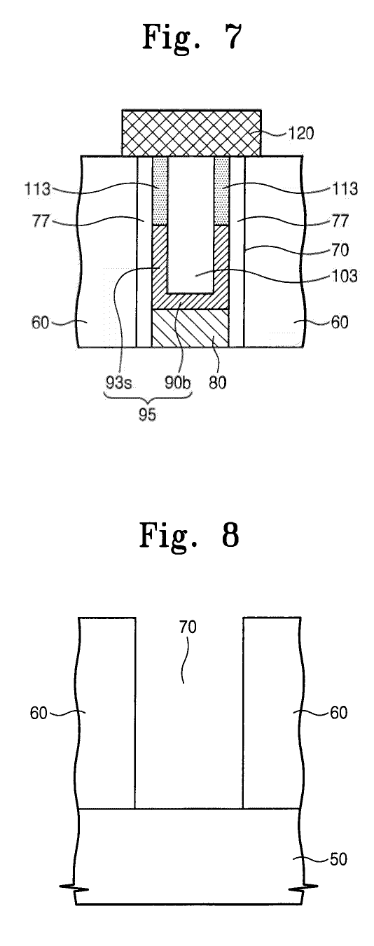

FIG. 7 is a sectional view of a phase change memory device according to further another embodiment of the present invention.

Referring to FIG. 6, the phase change memory device may be similar to the phase change memory device exemplarily described with respect to FIGS. 1 to 3 but an insulating spacer 77 may be provided on the sidewall of the opening 70. Accordingly, a contact area between the phase change material 113 and the first and second conductors 95 and 120 can be even more reduced. It will also be appreciated that the second conductor 120 of the phase change memory device shown in FIG. 7 may extend into the opening 70 as exemplarily described with respect to FIG. 6. Further, it will be appreciated that the phase change memory device shown in FIG. 7 may also include a seed layer such as that exemplarily described with respect to FIGS. 4 and 5.

FIGS. 8 through 14 are sectional views illustrating an exemplary method of forming a phase change memory device according to an embodiment of the present invention.

Referring to FIG. 8, a first insulating layer 60 is formed on the semiconductor substrate 50 to define an opening 70. The first insulating layer 60 may, for example, include an insulating material such as SiO, SiN, SiON, or the like or combinations thereof. The opening 70 may be formed by, for example, performing a photolithography process to remove a predetermined portion of the first insulating layer 60.

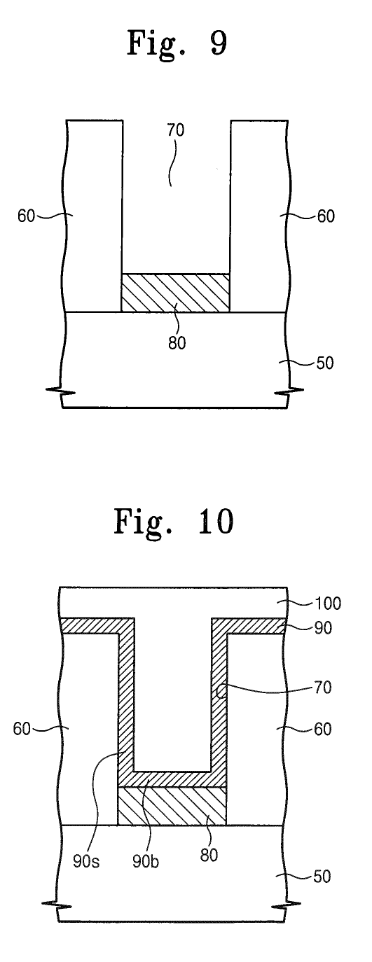

Referring to FIG. 9, a third conductor 80 is formed on the bottom of the opening 70. In one embodiment, the third conductor 80 may be formed by forming a conductive material on the first insulating layer to fill the opening 70 and then planarizing the conductive material (e.g., using a chemical mechanical polishing (CMP), an etch back process, or the like or combinations thereof) to remove a portion of the conductive material. The conductive material may, for example, include tungsten.

Referring to FIG. 10, a conductive material 90 is formed along the sidewall and the bottom of the opening 70. The conductive material 90 may include a first portion 90b on the bottom of the opening 70 and a second portion 90s on the sidewall of the opening 70. The conductive material 90 for the first conductor may, for example, include TiN. A second insulating material 100 is formed on the conductive material 90 to fill the opening 70. The second insulating layer 103 may, for example, include SiO, SiN, SiON, or the like or combinations thereof. In another embodiment, however, the second insulating layer 103 may, for example, include TiO, TaO, ZrO, MnO, HfO, MgO, InO, NbO, GeO, SbO, TeO, or the like or combinations thereof.

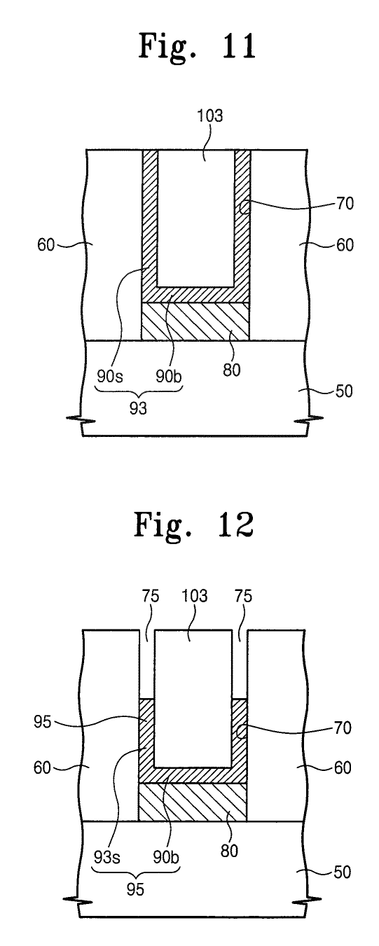

Referring to FIG. 11, a CMP process, an etch back process, or the like or combinations thereof is performed to remove the portions of the insulating material 100 and the conductive material 90 outside the opening 70 to form a conductive material pattern 93 defined in the opening 70 and the second insulating layer 103. As shown in FIG. 11, the conductive material pattern 93 includes the first portion 90b and the second portion 90s.

Referring to FIG. 12, the second portion 90s of the conductive material pattern 93 shown in FIG. 11 (e.g., the portion of the conductive material pattern 93 along the top sidewall of the opening 70) is partially removed to form the first conductor 95. The second portion 90s may be partially removed using, for example, an etch back process, a photolithography process, or the like or combinations thereof. Therefore, the top surface of the resultant second portion (herein identified at 93s) of the first conductor 95 is lower than the top surface of the second insulating layer 103 and an aperture 75 is defined between the first insulating layer 60 and the second insulating layer 103. In one embodiment, the second portion 90s of the conductive material pattern 93 shown in FIG. 11 may be partially removed such that the top surface of the resultant second portion 93s of the first conductor 95 is more than about 10 nm lower than the top surface of the first insulating layer 60. As a result, the height of the aperture 75 (e.g., as measured by the distance from the top surface of the second insulating layer 103 to the top surface of the second portion 93s of the first conductor 95) may be more than half the width of the opening 70. In one embodiment, the height of the second portion 93s of the first conductor 95 may be more than about 10 nm. As a result, the height of the second portion 93s of the first conductor 95 may be about 2.5 times less than the width of the opening 70. It will be appreciated, however, that the amount of removal of the conductive material pattern 93 may vary in accordance with the width of the opening 70 and thickness of the second portion 90s of the conductive material pattern.

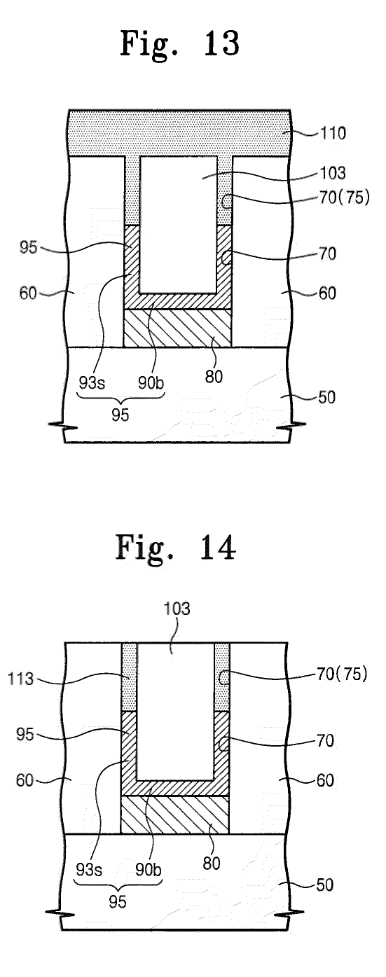

Referring to FIG. 13, a phase change material layer 110 is formed to fill the aperture 75. The phase change material layer 110 may be formed using, for example, a chemical vapor deposition (CVD) technique, an atomic layer deposition (ALD) technique, or the like or combinations thereof. The phase change material layer 110 may, for example, include a chalcogen compound such as Ge—Sb—Te(GST), Ge—Bi—Te (GBT), As—Sb—Te, As—Ge—Sb—Te, Sn—Sb—Te, In—Sn—Sb—Te, Ag—In—Sb—Te, 5A Group elements-Sb—Te, 6A Group elements-Sb—Te, 5A group elements-Sb—Se, 6A group elements-Sb—Se, or the like or combinations thereof, or a chalcogen compound including doped impurities and one or more of the above-listed chalcogen compounds. The impurities doped in the chalcogen compound may, for example, include N, O, Si, or the like or combinations thereof.

Referring to FIG. 14, a planarization process such as a CMP process, an etch back process, or the like or combinations thereof is performed to remove portions of the phase change layer outside the aperture 75, thereby forming the phase change material 113 confined within the aperture 75. A dry etching process may be applied as an etch back process to remove a portion of the phase change material layer 110. The dry etching process may use plasma or ion beam of an inert gas such as He, Ne, Ar, Kr, Xe, etc. A CMP process may be applied to selectively remove the phase change material layer 110 with respect to portions of the first and second insulating layers 60 and 103 outside the aperture 75.

Then, a conductive material is formed and patterned to form the second conductor 120, which is connected to the phase change material 113 as illustrated in FIG. 1. In one exemplary embodiment, the conductive material may include Ti and TiN, which are sequentially stacked.

According to the exemplary method described above, the phase change material layer 110 is formed after forming the second insulating layer 103. As a result, the processes associated with the formation of the second insulating layer 103 do not affect the formation of the phase change material layer 110. Because the phase change material layer 110 does not need to be considered, numerous conditions associated with the formation of the second insulating layer 103 can be set that would not otherwise be set if the second insulating layer 103 were to be formed after phase change material 113. For example, a low temperature process (e.g., below 300° C.) that does not affect the phase change material layer 113 may not be necessarily used for forming the second insulating layer 103. Moreover, the second insulating layer 103 can be formed under conditions (e.g., high temperature processes) sufficient to ensure excellent gap filling properties so that the second insulating layer 103 may be formed in the opening 70 without the formation of voids in the opening 70. For example, the second insulating layer 103 can be formed using a high temperature process (e.g., over 300° C.) to have excellent step coverage.

In one embodiment, although not illustrated, a seed layer such as the seed layer 130 exemplarily described with respect to FIG. 4 may be formed along the bottom and sidewall of the aperture 75 shown in FIG. 12, before forming the phase change material layer 110. The seed layer 130 helps the phase change material layer 110 be formed on the aperture 75, which is defined between the first and second insulating layers 60 and 103. In one embodiment, the seed layer 130 may be substantially amorphous and may serve as a nucleating layer for forming the phase change material layer 110. The seed layer 130 may, for example, include a material such as TiO, TaO, ZrO, MnO, HfO, MgO, InO, NbO, GeO, SbO, TeO, or the like or combinations thereof. In another embodiment, the seed layer 130 and the second insulating layer 103 may include substantially the same material. Thus, the phase change memory device may be formed to have the structure exemplarily described with respect to FIG. 4.

In one embodiment, an additional etch back process may be performed after planarizing the phase change material layer 110 to form the phase change material 113 shown in FIG. 14. After performing the additional etch back process, the top surface of the phase change material 113 shown in FIG. 14 may be lower than the top surface of the second insulating layer 103. Thus, the phase change memory device may be formed to have the structure exemplarily described with respect to FIG. 6.

In one embodiment, an insulating spacer such as the insulating spacer 77 exemplarily described with respect to FIG. 7 may be formed on the sidewall of the opening 70 before forming the third conductor 80 shown in FIG. 9. Thus, the phase change memory device may be formed to have the structure exemplarily described with respect to FIG. 7. In another embodiment, however, the insulating spacer may be formed on the sidewall of the opening 70 after forming the third conductor 80.

According to the exemplary method described above the third conductor 80 is formed after forming the first insulating layer 60 and the opening 70. In another embodiment, however, the third conductor 80 may be formed before forming the first insulating layer 60 and the opening 70. In such an embodiment, the first insulating layer 60 and the opening 70 may be formed after forming the third conductor 80 on the substrate.

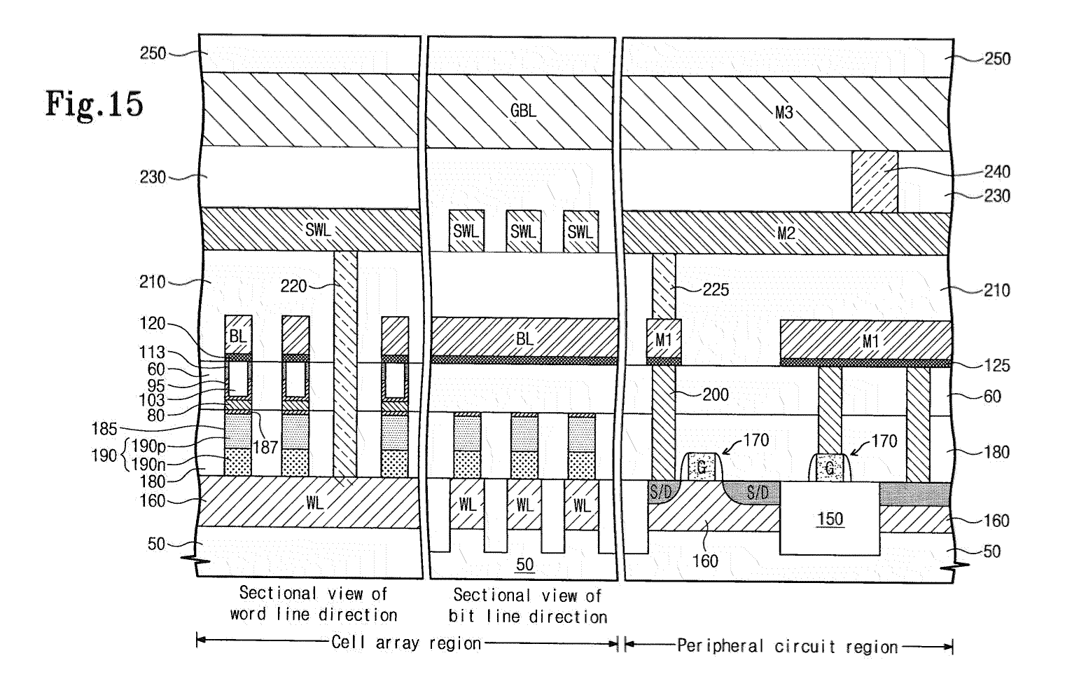

FIG. 15 is a sectional view of a memory cell array region and a peripheral circuit region in a phase change memory device according to one embodiment of the present invention. For clearer understanding, a word line direction (a direction toward which a word line extends) and a bit line direction (a direction toward which a bit line extends) are shown in a section of the memory cell array region. The left-illustrated cross-sectional view is the cross-section in the word line direction in the memory cell array region, the middle-illustrated cross-sectional view is the cross-section in the bit line direction in the memory cell array region and the right-illustrated cross-sectional view is the cross-section of the peripheral circuit region.

Referring to FIG. 15, a plurality of word lines WL are provided on a semiconductor substrate 50 in the memory cell array region. In one embodiment, the word lines WL are formed by providing semiconductor layer doped with an n-type impurity. In another embodiment, the word lines WL include a metallic layer. Adjacent word lines WL may be electrically insulated from each other by an insulting layer such as a device isolation layer 150. A driving device, e.g., a driving transistor 170, for driving the memory cell array region is provided on the active region 160, which is defined by device isolation layer 150 in the peripheral circuit region. A plurality of bit lines BL are provided on the semiconductor substrate 50 in the memory cell array region to cross over the word lines WL. In one embodiment, the bit line BL may be formed in the same processes used to form a first metal line M1 in the peripheral circuit region. The first metal line M1 may be electrically connected to a gate G and/or a source/drain region S/D of the driving transistor 170. The bit line BL and the first metal line M1 may, for example, include one or more metallic layers.

The word line WL may be provided on the semiconductor substrate 50 or may be provided in the semiconductor substrate 50. When the word line WL is formed by providing a semiconductor layer, the word line WL may be formed by implanting impurities into a predetermined region of the semiconductor substrate, by forming an epitaxial layer on the semiconductor substrate and implanting impurity into the epitaxial layer, by forming an epitaxial while doping impurity on the semiconductor substrate, or the like or combinations thereof.

The first metal line M1 is electrically connected to a gate G and/or source/drain S/D in the driving transistor 170 through a contact plug 200 in the peripheral circuit region.

In one embodiment, the phase change material 113 is disposed between the word line WL and the bit line BL and serves as a memory element within the memory cell array region. The first conductor 95, the third conductor 80, and a select device 190 are provided between the phase change material 113 and the word line WL while the second conductor 120 is provided between the phase change material 113 and the bit line BL. The first conductor 95 is electrically connected to the word line WL through the third conductor 80 and the select device 190. The second conductor 120 is electrically connected to the bit line BL.

The number and arrangement of first conductors 95 may correspond to the number and arrangement of phase change materials 113. Accordingly, each memory device may include a single first conductor 95 and a single phase change material 113. In one embodiment, the second conductor 120 may be commonly connected to the phase change material 113 of a plurality of memory devices along the bit line direction. In one embodiment, the number and arrangement of second conductors 120 may correspond to the number and arrangement of phase change materials 113 in a similar manner as described with respect to the first conductor 95.

In one embodiment, a barrier metal 125 may be provided between the first metal line M1 and the contact plug 200 at the peripheral circuit region. In another embodiment, the barrier metal 125 and the second conductor 120 may be formed in the same processes.

In one embodiment, the select device 190 is a diode. The diode 190 may, for example, include an n-type semiconductor 190n and a p-type semiconductor 190p, which are sequentially staked on the semiconductor substrate 50. The p-type semiconductor layer 190p is adjacent to the third conductor 80 and the n-type semiconductor layer 190n is adjacent to the word line WL. A silicide layer 187 may be provided to reduce a contact resistance between the diode 190 and the third conductor 80. The silicide layer 187 may, for example, include a metal silicide such as cobalt silicide, nickel silicide, titanium silicide, or the like or combinations thereof. In another embodiment, however, the select device 190 may be any suitable switching device or a MOS transistor.

A conductive line (hereinafter, referred to as a strapping word line (SWL)) that is electrically connected to the word line WL through the word line contact 220 may be provided on the bit line BL in the memory cell array region. The strapping word line SWL may reduce a resistance of the word line WL. A second metal line M2 may be provided on the first metal line M1 of the peripheral circuit region. In one embodiment, the strapping word line SWL and the second metal line M2 may be formed in the same processes. The strapping word line SWL and the second metal line M2 may, for example, include one or more metallic layers. The second metal line M2 may be electrically connected to the first metal line M1 through a via contact 225.

A global bit line GBL is provided on the strapping word line SWL and a third metal line M3 is provided on the second metal line M2. In one embodiment, the global bit line GBL and the third metal line M3 are formed in the same processes. In another embodiment, the global bit line GBL and the third metal line M3 may, for example, include one or more metallic layers. The third metal line M3 may be electrically connected to the second metal line M2 through the via contact 240.

A passivation layer 250 is provided on the global bit line GBL and the third metal line M3.

In one embodiment, the diode 190 may be provided within a first contact hole 185 defined through a third insulating layer 180. In one embodiment, a fourth insulating layer 210 may be formed between the bit line BL and the strapping word line SWL (and between the first metal line M1 and the second metal line M2). In one embodiment, a fifth insulating layer 230 may be provided between the strapping word line SWL and the global bit line GBL (and between the second metal line M2 and the third metal line M3).

The diode 190 may be provided in a first contact hole 185, which passes through the third insulating layer 180 and exposes the word line WL. Because the diode 190, the first conductor 95, and the phase change material 113 are defined in contact holes of insulating layers, the degree of integration with which a memory device can be formed may be improved. Moreover, a write current for changing the phase change material into a reset state of a high resistance or a set state of a low resistance can be reduced. In one embodiment, an insulating spacer 77 may be provided on the sidewall of the opening 70. Therefore, a contact area between the first conductor 95 an the phase change material 113 can be reduced even more and, as a result, the write current can be reduced further.

Word lines WL can be formed by forming device isolation layers 150 at predetermined regions of the semiconductor substrate 50, thereby forming a plurality of active regions for the word lines WL, followed by implanting impurity ions into the active regions. In one embodiment, word lines WL in active regions of the memory cell array region and active regions 160 in the peripheral circuit region may be formed simultaneously. For example, when the semiconductor substrate 50 is a p-type semiconductor substrate, n-type impurity ions may be implanted to form word lines WL and the active regions 160. In another embodiment, however, the word lines WL may be formed using various methods (e.g., by forming a plurality of parallel epitaxial semiconductor patterns on the semiconductor substrate 50 and implanting impurity ions into the epitaxial semiconductor patterns, or the like). In such an embodiment, the MOS transistor 170 may then be formed on the active region 160 in the peripheral circuit region after forming the word lines WL using any suitable method.

The first contact hole where the diode 190 is provided may be formed by patterning the third insulating layer 180. The diode 190 may be formed by, for example, forming a semiconductor layer including Ge, Si, GeSi, or the like or combinations thereof in the first contact hole 185 and implanting impurities. The semiconductor layer in the first contact hole 185 may be formed by, for example, a selective epitaxial growth (SEG) technique or a solid phase epitaxial technique. The SEG technique may be performed using a portion of the word line WL that is exposed by the first contact hole 185 as a seed layer to grow an epitaxial layer. The solid phase epitaxial technique, however, may be performed by forming an amorphous semiconductor layer or a polycrystalline semiconductor layer in the first contact hole 185, and then crystallizing the semiconductor layer formed in the first contact hole 185.

The second conductor 120 and the bit line BL may be formed on the phase change material by forming one or more metallic layers and patterning the one or more metallic layers. In one embodiment, the second conductor 120 and the bit line BL may be formed using a damascene process. When forming the bit line BL in the memory cell array region, a first metal line M1 may be formed in a peripheral circuit region. A contact plug 200 for connecting the first metal line M1 with a gate G and/or source/drain S/D may be formed by patterning the first insulating layer 60 and the third insulating layer 180 to form a contact hole and filling resultant contact hole with a metallic layer. In one embodiment, the contact plug 200 and the first metal line M1 may be formed in a single process. For example, the first insulating layer 60 and the third insulating layer 180 may be patterned to form a contact hole, a metallic layer may the be formed in the contact hole and on the third insulating layer 130, and the metallic layer may be patterned to simultaneously form the contact plug 200 and the first metal line M1.

After forming the bit line BL and the first metal line M1, a fourth insulating layer 210 is formed. Next, a strapping word line SWL and a second metal line M2 are formed on the fourth insulating layer 210. The second metal line M2 may be electrically connected to the first metal line M1 through the via contact 225 formed in the fourth insulating layer 210. The strapping word line SWL is connected to the word line WL by the word line contact 220 passing through the fourth, third and first insulating layers 210, 60, and 180, respectively. In one embodiment, the word line contact 220 and the via contact 225 may be formed by patterning the insulating layers to form contact holes and filling theses contact holes with a metal. In such an embodiment, the via contact 225 and the second metal line M2 may be simultaneously formed.

After forming the strapping word line SWL and the second metal line M2, a fifth insulating layer 230 is formed. Next, the global bit line GBL and the third metal line M3 are formed on the fifth insulating layer 230. The third metal line M3 is electrically connected to the second metal line M2 through a via contact 240 passing through the fifth insulating layer 230.

As exemplarily shown in FIG. 15, each of the first to fifth insulating layers and the passivation layer 250 are described as single layers. It will be appreciated, however, that any of the first to fifth insulating layers and the passivation layer 250 may be formed of multi-layers. Likewise, while the gate, metal lines M1, M2, and M3, bit line BL, strapping word line SWL, contacts, contact plugs, and via contacts are described as single layers, any of these structures may be formed of multi-layers.

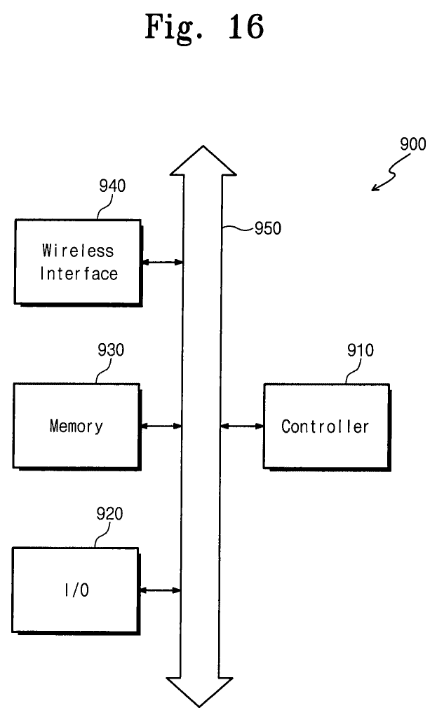

FIG. 16 is a view of one embodiment of a system including a phase change memory device.

Referring to FIG. 16, the system 900 may be used in a wireless communication device such as PDAs, laptop computers, portable computers, web tablets, wireless telephones, mobile phones, and digital music players, or all devices capable of receiving and/or transmitting information (e.g., in a wireless environment).

The system 900 may, for example, include a controller 910, an input/output device 920 (e.g., a keypad, a keyboard, a display, or the like or combinations thereof), a memory 930, and a wireless interface 940, which are connected through a bus 950. The controller 910 includes, for example, at least one microprocessor (e.g., including a digital signal processor, a microcontroller, or the like or combinations thereof). The memory 930 stores commands executed by the controller 910. The memory 930 may also store user data. The memory 930 includes a phase change memory according to the embodiments exemplarily described above. It will also be appreciated that the memory 930 may further comprise different types of memory (e.g., a volatile memory for arbitrary access at any time) and numerous kinds of memory other than (or including) phase change memory.

The system 900 may use a wireless interface to transmit and receive data into and from a wireless communication network that is communicating through an RF signal. For example, the wireless interface 940 includes an antenna, wireless transceiver, or the like or combinations thereof.

The system 900 may be used in a communication interface protocol of a third generation communication system such as CDMA, GSM, NADC, E-TDMA, WCDAM, CDMA2000, or the like or combinations thereof.

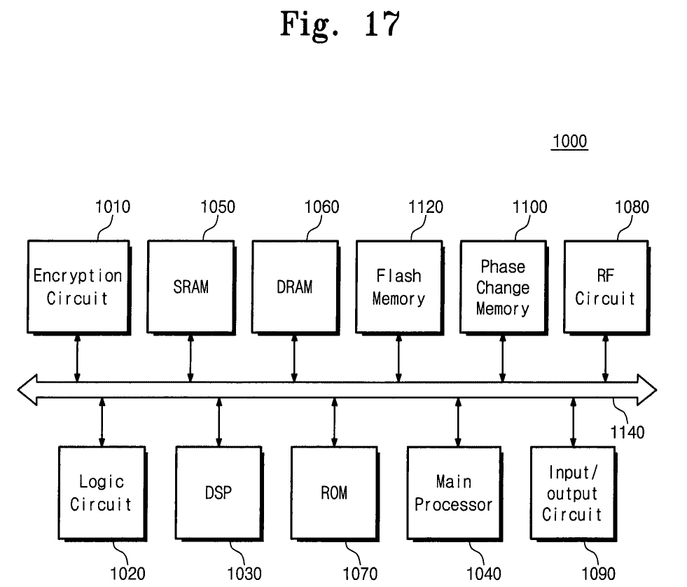

In one embodiment, the semiconductor device and/or a phase change memory device of exemplarily described above may be applied to a memory card. FIG. 17 is a block diagram of one embodiment of a memory card with a phase change memory device.

Referring to FIG. 17, the memory card 1000 includes an encryption circuit 1010 for encryption, a logic circuit 1020, a digital signal processor (DSP) 1030 for an exclusive processor, and a main processor 1040. Additionally, the memory card system 1000 includes a phase change memory device 1100, and different kinds of memory, e.g., SRAM 1050, DRAM 1060, ROM 1070, and a flash memory 1120. The memory card system 1000 includes an RF circuit 1080 and an input/output circuit 1090. Function blocks 1010 to 1120 in the memory card 1000 are connected to each other through the system bus 1140.

The memory card 1000 operates according to the control of an external host (not shown), and the phase memory device 1100 of the present invention stores data or outputs the stored data according to the control of the host.

According to one embodiment exemplarily described above, a contact area between the phase change material and conductors can be minimized. According to one embodiment exemplarily described above, a phase change memory device capable of operating with low power can be provided. According to one embodiment exemplarily described above, a high degree of integration in the phase change memory device can be achieved. According to one embodiment exemplarily described above, a multi-level phase change device can be provided.

According to some embodiments, a memory device may comprise a first insulating layer provided on a substrate, a first conductor, a variable resistor and a second conductor. The first insulating layer defines an opening. The first conductor may include a first portion and a second portion. The first portion of the first conductor is provided on a bottom of the opening of the first insulating layer. The second portion of the first conductor is provided on a sidewall of the opening of the first insulating layer. The variable resistor is connected to the second portion of the first conductor and is provided on the sidewall of the opening of the first insulating layer. The second conductor is provided on the variable resistor.

According to other embodiments, a method for forming a memory device may comprise forming a first insulating layer on a substrate to define a first opening; forming a first conductive layer on a bottom and a sidewall of the first opening; forming a second insulating layer on the first conductive layer in the first opening; removing a portion of the first conductive layer formed on the sidewall of the first opening to form a first conductor, a second opening being defined between the second insulating layer and the first insulating layer; forming a phase change material in the second opening, the phase change material being connected to the first conductor; and forming a second conductor on the phase change material.

In such a method, the second opening may have a ring shape. Further, before the forming of the phase change material, a seed layer may be formed in the second opening. The seed layer may include TiO, TaO, ZrO, MnO, HfO, MgO, InO, NbO, GeO, SbO, TeO, or combinations thereof.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A memory device comprising:
a first insulating layer provided on a substrate, the first insulating layer including an opening defined therein;
a first conductor provided within the opening, the first conductor including a first portion provided on a bottom of the opening and a second portion provided along a sidewall of the opening;
a variable resistor provided along the sidewall of the opening, the variable resistor being connected to the second portion of the first conductor; and
a second conductor provided on the variable resistor.

2. The memory device of claim 1, wherein a width of the variable resistor is less than a width of the first portion of the first conductor.

3. The memory device of claim 1, further comprising a second insulating layer provided in the opening,
wherein the second portion of the first conductor and the variable resistor are disposed between the first insulating layer and the second insulating layer.

4. The memory device of claim 3, wherein the second insulating layer comprises silicon oxide, silicon nitride, silicon oxide nitride, or combinations thereof.

5. The memory device of claim 3, further comprising a seed layer disposed between the second insulating layer and the variable resistor and between the variable resistor and the second portion of the first conductor.

6. The memory device of claim 5, wherein the seed layer comprises TiO, TaO, ZrO, MnO, HfO, MgO, InO, NbO, GeO, SbO, TeO, or combinations thereof.

7. The memory device of claim 3, wherein the variable resistor comprises a phase change material.

8. The memory device of claim 7, wherein the phase change material comprises an XY compound, wherein “X” comprises Te, Se, S, Po, or combinations thereof, and “Y” comprises Sb, As, Ge, Sn, P, O, In, Bi, Ag, Au, Pd, Ti, B, N, Si, or combinations thereof.

9. The memory device of claim 7, wherein the second insulating layer comprises silicon oxide, silicon nitride, silicon oxide nitride, or combinations thereof.

10. The memory device of claim 7, wherein the first portion of the first conductor has a ring shape.

11. The memory device of claim 7, wherein the variable resistor has a ring shape.

12. The memory device of claim 7, wherein a contact area between the variable resistor and the first region of the first conductor and a contact area between the variable resistor and the second conductor have a ring shape.

13. The memory device of claim 1, further comprising an insulating spacer between the sidewall of the opening and the second portion of the first conductor.

14. The memory device of claim 1, wherein a height of the variable resistor along the sidewall of the opening is more than half the width of the opening.

15. The memory device of claim 1, wherein a portion of the second conductor extends into the opening.

16. The memory device of claim 1, wherein a width of the variable resistor is substantially equal to or less than a width of the second portion of the first conductor.

17. A semiconductor device, comprising:
a substrate;
a first conductor including a first portion and a second portion, wherein a width of the first portion of the first conductor is greater than a width of second portion of the first conductor;
a second conductor; and
a variable resistor connected between the second portion of the first conductor and the second conductor, wherein a width of the variable resistor is less than the width of the first portion of the first conductor.

18. The semiconductor device of claim 17, further comprising a first insulating material on the substrate, the first insulating material including a first upper surface, a first lower surface, and a first side surface connecting the first upper and lower surfaces,
wherein the second portion of the first conductor contacts the first side surface, and
wherein the variable resistor contacts the first side surface of the first insulating material.

19. The semiconductor device of claim 18, further comprising a second insulating material on the substrate, the second insulating material including a second upper surface, a second lower surface, and a second side surface connecting the second upper and lower surfaces,
wherein the first portion of the first conductor contacts the second lower surface of the second insulating material,
wherein the second portion of the first conductor contacts a portion of the second side surface of the second insulating material, and
wherein the variable resistor contacts another portion of the second side surface of the second insulating material.

20. A memory device comprising:
a first insulating layer provided on a substrate, the first insulating layer having an opening therein;
a first conductor provided within the opening, the first conductor including a first portion and a second portion, the first portion provided on a bottom of the opening, the second portion provided on a sidewall of the opening;
a phase change material provided along the sidewall of the opening, the phase change material connected to the second portion of the first conductor; and
a second conductor provided on the phase change material,
wherein the second portion of the first conductor and the phase change material are disposed between the first insulating layer and the second insulating layer.

21. The memory device of claim 20, wherein the second insulating layer comprises silicon oxide, silicon nitride, silicon oxide nitride, or combinations thereof.

22. The memory device of claim 20, further comprising a seed layer disposed between the phase change material and the first insulating layer, the phase change material and the second insulating layer, and the phase change material and the second portion of the first conductor.

23. The memory device of claim 22, wherein the seed layer comprises TiO, TaO, ZrO, MnO, HfO, MgO, InO, NbO, GeO, SbO, TeO, or combinations thereof.

24. The memory device of claim 20, wherein an overlapping region between the phase change material and the first portion of the first conductor and an overlapping region between the phase change material and the second conductor have a ring shape.

25. The memory device of claim 20, wherein the phase change material and the second portion of the first conductor have a ring shape.

26. The memory device of claim 20, wherein the phase change material has a narrower width than the first portion of the first conductor.

27. A method for forming a memory device, the method comprising:
forming a first insulating layer on a substrate, the first insulating layer having a first opening therein;
forming a first conductive layer on a bottom and a sidewall of the first opening;
forming a second insulating layer on the first conductive layer in the first opening;
removing a portion of the first conductive layer formed on the sidewall of the first opening to form a first conductor, and a second opening between the second insulating layer and the first insulating layer;
forming a phase change material in the second opening, the phase change material being connected to the first conductor; and
forming a second conductor on the phase change material.

28. The method of claim 27, wherein the second opening has a ring shape.

29. The method of claim 27, before the forming of the phase change material, further comprising forming a seed layer in the second opening.

30. The method of claim 29, wherein the seed layer includes comprises TiO, TaO, ZrO, MnO, HfO, MgO, InO, NbO, GeO, SbO, TeO, or combinations thereof.
